(19) United States
(12) Patent Application Publication
(10) Pub. No.: US 2025/0366355 A1
(43) Pub. Date: Nov. 27, 2025

(54) DISPLAY DEVICE AND DISPLAY SYSTEM INCLUDING DISPLAY DEVICE

(71) Applicant: Samsung Display Co., LTD., Yongin-si (KR)

(72) Inventors: Tae Ho KIM, Yongin-si (KR); Oh Jeong KWON, Yongin-si (KR); Jong Ho SON, Yongin-si (KR); Dae Won KIM, Yongin-si (KR); Mi Hwa LEE, Yongin-si (KR); Sung Gyu JANG, Yongin-si (KR)

(73) Assignee: Samsung Display Co., LTD., Yongin-si (KR)

(21) Appl. No.: 18/975,284

(22) Filed: Dec. 10, 2024

(30) Foreign Application Priority Data
May 21, 2024 (KR) 10-2024-0065891

(51) Int. Cl. H10K 59/80; H10K 59/38

(52) U.S. Cl. CPC H10K 59/879; H10K 59/38

(57) ABSTRACT

A display device includes a substrate including a display area and a non-display area surrounding the display area, a pixel circuit layer disposed on the substrate, a light emitting element layer which is disposed on the pixel circuit layer and includes light emitting elements, and a filter layer which is disposed on the light emitting element layer and includes filters respectively overlapping the light emitting elements. Each of the filters has metal layers and a dielectric layer disposed between the metal layers, and centers of the filters are shifted from centers of the light emitting elements.

### CROSS-REFERENCE TO RELATED APPLICATION

This application claims priority to and benefits of Korean patent application No. 10-2024-0065891 under 35 U.S.C. § 119, filed on May 21, 2024 in the Korean Intellectual Property Office, the entire contents of which are incorporated herein by reference.

### BACKGROUND

### 1. Technical Field

This disclosure relates to a display device and a display system including the display device.

### 2. Description of the Related Art

Recently, as interest in information displays has increased, research and development on display devices have been continuously conducted.

In particular, an organic light emitting diode (OLED) is an active light emitting display element. It offers advantages such as a wide viewing angle, excellent contrast, low voltage operation, lightweight and thin configuration, and high response speed. As a result, OLEDs have attracted significant attention as a next-generation display element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved efficiency. For example, in the display device, centers of filters may be shifted from centers of light emitting elements. This configuration helps maintain the color reproduction range of the entire display panel and improves light recycling efficiency.

The disclosure provides a display device, which may include: a substrate including a display area and a non-display area surrounding the display area; a pixel circuit layer disposed on the substrate; a light emitting element layer disposed on the pixel circuit layer, the light emitting element layer including light emitting elements; and a filter layer disposed on the light emitting element layer, the filter layer including filters, each filter overlapping a corresponding light emitting element, wherein each filter includes metal layers and a dielectric layer disposed between the metal layers, and wherein centers of the filters are shifted from centers of corresponding light emitting elements.

In an embodiment, the light emitting elements may include anode electrodes disposed on the pixel circuit layer and positioned adjacent to each other. The centers of the light emitting elements may align with centers of the anode electrodes.

In an embodiment, a center of a first filter among the filters may be shifted by a first distance in either a first direction or a second direction intersecting the first direction from a center of a first anode electrode among the anode electrodes. A center of a second filter among the filters may be shifted by a second distance, different from the first distance, in either the first direction or the second direction from a center of a second anode electrode among the anode electrodes.

In an embodiment, a first light emitting element, including the first anode electrode, and a second light emitting element, including the second anode electrode, among the light emitting elements may emit light of a same color.

In an embodiment, the centers of the filters may be shifted by a first distance from the centers of the anode electrodes at a first position adjacent to a center of the display area, and be shifted by a second distance, greater than the first distance, at a second position adjacent to the non-display area.

In an embodiment, light emitted from the display device may have a chief ray angle for each position of the display area. A center of each filter may be shifted from a center of a corresponding light emitting element based on the chief ray angle at a corresponding position.

In an embodiment, the chief ray angle may be greater than about 0 degree and less than 30 degrees.

In an embodiment, the chief ray angle may have a first angle at the first position adjacent to the center of the display area, and a second angle, greater than the first angle, at the second position adjacent to the non-display area.

In an embodiment, the light emitting elements may include a first light emitting element that emits light of a first color, a second light emitting element that emits light of a second color, and a third light emitting element that emits light of a third color. The filters may include a first filter overlapping the first light emitting element, a second filter overlapping the second light emitting element, and a third filter overlapping the third light emitting element. The first, second, and third filters may have different thicknesses.

In an embodiment, the first color may be red, the second color may be green, and the third color may be blue. A thickness of the first filter may be less than a thickness of the second filter, and a thickness of the third filter may be greater than the thickness of the second filter.

In an embodiment, the dielectric layers of the first, second, and third filters may have different thicknesses.

In an embodiment, the filters may have thicknesses of less than or equal to about 0.2 μm.

In an embodiment, the display device may further include: a polarizing layer disposed on the filter layer; and a phase retardation layer disposed between the filter layer and the polarizing layer.

In an embodiment, the polarizing layer may include a linear polarizer that transmits linearly polarized light from the display device.

In an embodiment, the light emitting elements may further include anode electrodes disposed on the pixel circuit layer a light emitting structure disposed on the anode electrodes that includes a plurality of light generation layers. The light emitting structure may include at least two light emitting units that are sequentially stacked, with at least one charge generation layer disposed between the light emitting units. Each of the at least two light emitting units may include a light emitting layer.

The disclosure provides a display system, which may include: a processor to provide input image data; and a display device to display an image based on the input image data, wherein the display device includes a substrate including a display area and a non-display area surrounding the display area, a pixel circuit layer disposed on the substrate, a light emitting element layer disposed on the pixel circuit layer, the light emitting element layer including light emitting elements and a filter layer disposed on the light emitting element layer, the filter layer including filters, each filter overlapping a corresponding light emitting element, wherein each filter includes metal layers and a dielectric layer disposed between the metal layers, and centers of the filters are shifted from centers of corresponding light emitting elements.

### BRIEF DESCRIPTION OF THE DRAWINGS

The above and other aspects and features of the disclosure will become more apparent from the detailed description of embodiments with reference to the accompanying drawings, in which:

FIG. 1 is a schematic block diagram illustrating an embodiment of a display device according to the disclosure.

FIG. 2 is a schematic block diagram illustrating an embodiment of any of the sub-pixels shown in FIG. 1.

FIG. 3 is a schematic plan view illustrating an embodiment of a display panel shown in FIG. 1.

FIG. 4 is an exploded schematic perspective view illustrating a portion of the display panel shown in FIG. 3.

FIG. 5 is a schematic plan view illustrating an embodiment of any of the pixels shown in FIG. 4.

FIG. 6 is a schematic sectional view taken along line I-I′ in FIG. 3.

FIG. 7 is a schematic sectional view illustrating an embodiment of light emission according to a position of the display panel shown in FIG. 1.

FIGS. 8 and 9 are enlarged schematic views illustrating portion A in FIG. 6.

FIG. 10 is a table illustrating an embodiment of a chief ray angle and a shifted distance for each position of the display panel.

FIGS. 11 and 12 are schematic sectional views illustrating embodiments of a light emitting structure included in any of first, second, and third light emitting elements shown in FIG. 6.

FIGS. 13 and 14 are schematic plan views illustrating other embodiments of one of the pixels shown in FIG. 4.

FIG. 15 is a schematic block diagram illustrating an embodiment of a display system.

FIG. 16 is a schematic perspective view illustrating an application example of the display system shown in FIG. 15.

FIG. 17 is a schematic view illustrating a head-mounted display device shown in FIG. 16, worn by a user.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, the sizes, thicknesses, ratios, and dimensions of the elements may be exaggerated for ease of description and for clarity. Like numbers refer to like elements throughout.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

The phrase “in a plan view” means viewing the object from the top, and the phrase “in a schematic sectional view” means viewing a cross-section of which the object is vertically cut from the side. Hence, the expression “in a plan view” used herein may mean that an object is viewed in the third z direction from the top. The phrase “in a schematic sectional view” means viewing a cross-section in the first x direction or the second y direction of which the object is vertically cut from the side. The third z direction also can be referred to as a “thickness direction.”

In the specification, it will be understood that when an element (or region, layer, part, etc.) is referred to as being “on,” “connected to,” or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the disclosure, when an element is “directly on,” “directly connected to,” or “directly coupled to” another element, there are no intervening elements present. For example, “directly on” may mean that two layers or two elements are disposed without an additional element such as an adhesion element therebetween.

It should be understood that the terms “comprise,” “include,” “have,” and the like are intended to specify the presence of stated features, integers, steps, operations, elements, components, and/or combinations of them but do not preclude the presence or addition of one or more other features, integers, steps, operations, elements, components, and/or combinations thereof.

The term “at least one of” is intended to include the meaning of “at least one selected from” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms “first,” “second,” etc. may be used herein to describe various elements, these elements should not be limited by these terms. These terms are only used to distinguish one element from another element. For instance, a “first” element could be termed a “second” element without departing from the teachings of the disclosure. Similarly, a “second” element could also be termed a “first” element, without departing from the teachings of the disclosure.

Spatially relative terms, such as “below,” “beneath,” “lower,” “above,” “upper,” or the like, may be used herein for ease of description to explain the relationships between one element or component and another as illustrated in the drawings. It will be understood that these spatially relative terms, as well as the illustrated configurations, are intended to encompass different orientations of the device in use or operation, beyond the orientation shown in the drawings. For example, in the case where a device shown in the drawings is turned over, elements described as “below” or “beneath” another elements or features may be oriented “above” them. Similarly, the term “above” may include orientations where an element is both upper and lower relative to another. The device may also be oriented differently (e.g., rotated 90 degrees or at other angles), and the spatially relative terms may be interpreted differently depending on the orientations.

As used herein, the expressions used in the singular such as “a,” “an,” and “the,” are intended to include the plural forms as well, unless the context clearly indicates otherwise.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, 10%, or 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The embodiments of the disclosure are described with reference to schematic diagrams of embodiments (and an intermediate structure) of the disclosure. Variations in shape shown, due to factors such as manufacturing processes and/or tolerances, may occur. Therefore, the embodiments of the disclosure are not limited to the specific shapes of regions illustrated here but include deviations in shape caused by, for example, manufacturing processes. The regions depicted in the drawings are schematic in nature, and their shapes do not represent the actual shapes of the device regions, nor do they limit the scope of the disclosure.

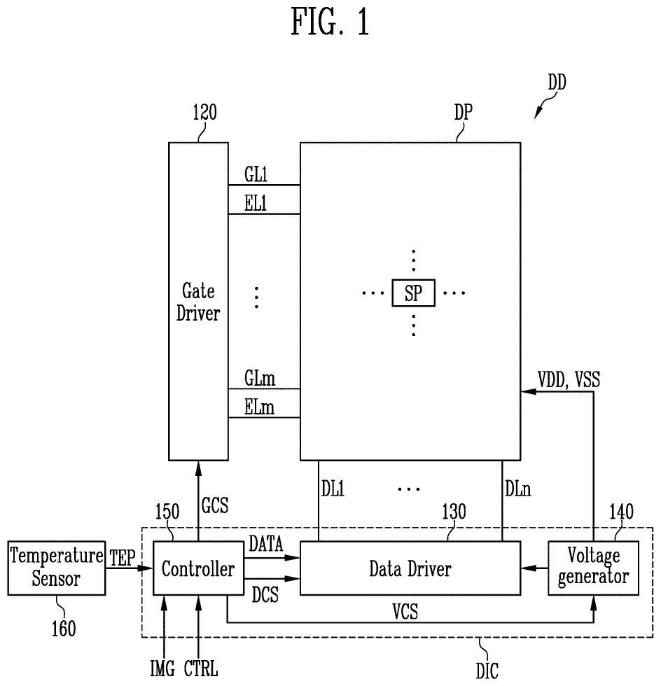

FIG. 1 is a schematic block diagram illustrating an embodiment of a display device of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element that generates light. For example, each of the sub-pixels SP may generate light of a specific color such as red, green, blue, cyan, magenta, or yellow. Two or more sub-pixels among the sub-pixels SP may form one pixel. For example, three sub-pixels SP may form one pixel.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied, and the like.

In embodiments, first to m-th light emitting control lines EL1 to ELm connected to the sub-pixels SP in the row direction may be further provided. The gate driver 120 may include an emission control driver that controls the first to m-th emission control lines EL1 to ELm, and the emission control driver may operate under the control of the controller 150.

The gate driver 120 may be disposed at a side of the display panel DP. However, embodiments are not limited thereto. For example, the gate driver 120 may be divided into two or more drivers which are physically and/or logically divided, and these drivers may be disposed on a side of the display panel DP and on the opposite side of the display panel DP. In some embodiments, the gate driver 120 may be disposed in various configurations at the periphery of the display panel DP.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals with grayscale voltages corresponding to the image data DATA to the first to n-th data lines DL1 to DLn using voltages from the voltage generator 140. In the case where a gate signal is applied to each of the first to m-th gate lines GL1 to GLm, data signals that correspond to the image data DATA may be applied to the data lines DL1 to DLm. Accordingly, corresponding sub-pixels SP may generate light that corresponds to the data signals, thereby enabling an image to be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages and provide the generated voltages to components of the display device DD. For example, the voltage generator 140 may generate a plurality of voltages by receiving an input voltage from outside the display device DD, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, while the second power voltage VSS may have a voltage level lower than that of the first power voltage VDD. In other embodiments, the first power voltage VDD or the second power voltage VSS may be supplied by an external device to the display device DD.

In embodiments, the voltage generator 140 may generate various voltages. For example, the voltage generator 140 may generate an initialization voltage that is applied to the sub-pixels SP. For example, a selected reference voltage may be applied to the first to n-th data lines DL1 to DLn during a sensing operation for sensing electrical characteristics of transistors and/or light emitting elements of the sub-pixels SP. The voltage generator 140 may generate the reference voltage.

The controller 150 may control overall operations of the display device DD. The controller 150 may receive input image data IMG and a control signal CTRL from an external source to control the display of the input image data IMG. The controller 150 may provide the gate control signal GCS, the data control signal DCS, and the voltage control signal VCS in response to the control signal CTRL.

The controller 150 may convert the input image data IMG to a format suitable for the display device DD or the display panel DP, thereby outputting the image data DATA. In embodiments, the controller 150 may align the input image data IMG to be suitable for the sub-pixels SP in row units, thereby outputting the image data DATA.

Two or more components among the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be functionally separate components in a single driver integrated circuit DIC. In other embodiments, at least one of the data driver 130, the voltage generator 140, and the controller 150 may be provided as a separate component, distinct from the driver integrated circuit DIC.

The display device DD may include at least one temperature sensor 160. The temperature sensor 160 may sense a temperature at its periphery and generate temperature data TEP indicating the sensed temperature. In embodiments, the temperature sensor 160 may be disposed adjacent to the display panel DP and/or the driver integrated circuit DIC.

The controller 150 may control various operations of the display device DD in response to the temperature data TEP. In embodiments, the controller 150 may adjust the luminance of an image output from the display panel DD in response to the temperature data TEP. For example, the controller 150 may control components such as the data driver 130 and/or the voltage generator 140, thereby adjusting data signals and the first and second power voltages VDD and VSS.

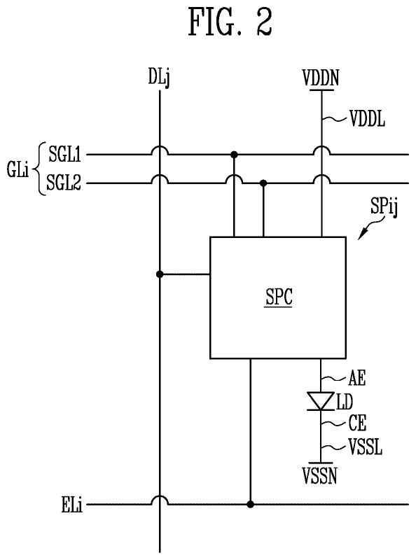

FIG. 2 is a schematic block diagram illustrating an embodiment of any of the sub-pixels shown in FIG. 1. In FIG. 2, a sub-pixel SPij is disposed on an i-th row (i is an integer greater than or equal to 1 and less than or equal to m) and a j-th column (j is an integer greater than or equal to 1 and less than or equal to n) among the sub-pixels SP shown in FIG. 1.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1. An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC. Accordingly, a current may flow from the first power voltage node VDDN to the second power voltage node VSSN. The light emitting element LD may emit light according to an amount of current flowing through it.

The sub-pixel circuit SPC may be connected to an i-th gate line GLi among the first to m-th gate lines GL1 to GLm shown in FIG. 1, an i-th emission control line ELi among the first to m-th emission control lines EL1 to ELm shown in FIG. 1, and a j-th data line DLj among the first to n-th data lines DL1 to DLn shown in FIG. 1. The sub-pixel circuit SPC may control the light emitting element LD according to signals received through these signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In the case where the i-th emission control line ELi includes two or more sub-emission control lines, the sub-pixel circuit SPC may operate in response to emission control signals received through the corresponding emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the i-th emission control line ELi. Accordingly, the light emitting element LD may generate light with a luminance corresponding to the data signal.

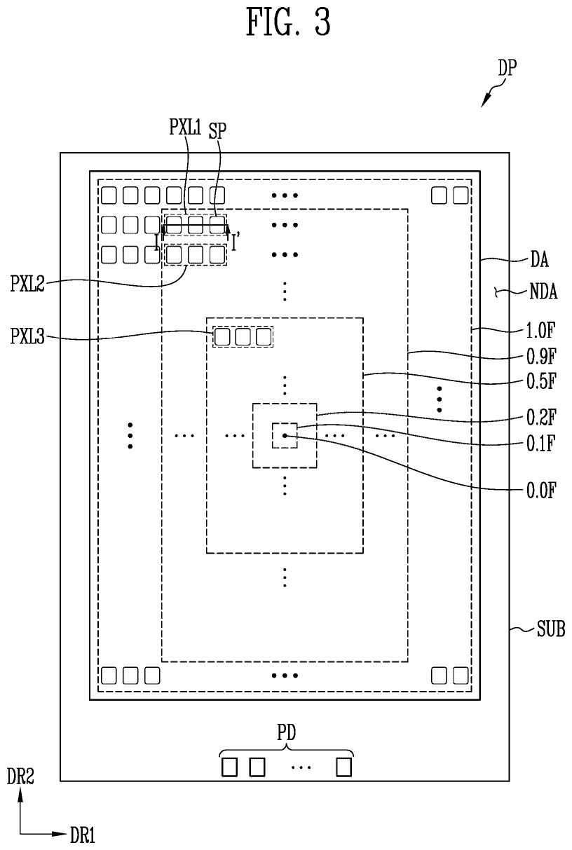

FIG. 3 is a schematic plan view illustrating an embodiment of the display panel shown in FIG. 1.

Referring to FIG. 3, the embodiment of the display panel DP shown in FIG. 1 may include a display area DA and a non-display area NDA. The display panel DP may display an image through the display area DA. The non-display area NDA may be disposed surrounding the display area DA.

The display panel DP may include a substrate SUB, sub-pixels SP, and pads PD.

In the case where the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. Therefore, the sub-pixels SP may need to have a relatively high degree of integration. In order to increase the degree of integration of the sub-pixels SP, the substrate SUB may be provided as a silicon substrate. The sub-pixels SP and/or the display panel DP may be formed on the substrate SUB as the silicon substrate. The display device DD (see FIG. 1) including the display panel DP formed on the substrate SUB as the silicon substrate may be referred to as an OLED on Silicon (OLEDOS) display device.

The sub-pixels SP may be disposed in the display area DA on the substrate SUB. The sub-pixels SP may be arranged in a matrix form along a first direction DR1 and a second direction DR2 that intersects the first direction DR1. However, embodiments are not limited to this arrangement. For example, the sub-pixels SP may be arranged in a zigzag pattern along the first direction DR1 and the second direction DR2. For example, the sub-pixels SP may be disposed in a PENTILE™ form. The first direction DR1 may be a row direction, and the second direction DR2 may be a column direction.

Two or more sub-pixels among the sub-pixels SP may form one pixel PXL. For example, three sub-pixels SP may form one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn, as shown in FIG. 1, may be disposed in the non-display area NDA.

At least one of the gate driver 120, the data driver 130, the voltage generator 140, the controller 150, and the temperature sensor 160, as shown in FIG. 1, may be integrated in the non-display area NDA of the display panel DP. In embodiments, the gate driver 120 shown in FIG. 1 is mounted on the display panel DP and may be disposed in the non-display area NDA. In other embodiments, the gate driver 120 may be implemented as an integrated circuit distinct from the display panel DP. In embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device DD (see FIG. 1). In embodiments, voltages and signals necessary for the operation of components included in the display panel DP may be provided from the driver integrated circuit DIC shown in FIG. 1 through the pads PD. For example, the first to n-th data lines DL1 to DLn may be connected to the driver integrated circuit DIC through the pads PD. For example, the first and second power voltages VDD and VSS may be supplied from the driver integrated circuit DIC through the pads PD. in the case where the gate driver 120 is mounted on the display panel DP, the gate control signal GCS may be transmitted from the driver integrated circuit DIC to the gate driver 120 via the pads PD.

In embodiments, a circuit board may be electrically connected to the pads PD using a conductive adhesive member, such as an anisotropic conductive film. The circuit board may be a Flexible Printed Circuit Board (FPCB) or a flexible film, which has a flexible material. The driver integrated circuit DIC may be mounted on the circuit board and electrically connected to the pads PD.

In embodiments, the display area DA may have various shapes. The display area DA may have a closed-loop shape with linear and/or curved sides. For example, the display area DA may have shapes such as a polygon, circle, semicircle, or ellipse.

In embodiments, the display area DA may be defined in field units divided according to positions. For example, a center of the display area DA may be defined as 0.0 F, and an edge of the display area DA adjacent to the non-display area NDA may be defined as 1.0 F. The display area DA may be divided from 0.0 F to 1.0 F based on position. For example, the display area DA may be divided at equal intervals in the first direction DR1 or the second direction DR2 intersecting the first direction DR1, centered at 0.0 F, to define multiple areas. The display area DA may be divided at 0.1 F intervals from 0.0 F to 1.0 F based on position (fields), such that each pixel PXL may be included in any of 0.1 F, 0.2 F, . . . , 0.9 F, and 1.0 F. A pixel corresponding to a position closest to the center of the display area DA may be defined as 0.1 F. However, this is merely illustrative, and the interval at which the display device DA is divided is not limited to 0.1 F.

In embodiments, the display panel DP may have a flat display surface. In other embodiments, the display panel DP may have at least a partially rounded display surface. In embodiments, the display panel DP may be bendable, foldable, or rollable. The display panel DP and/or the substrate SUB may include materials with flexibility.

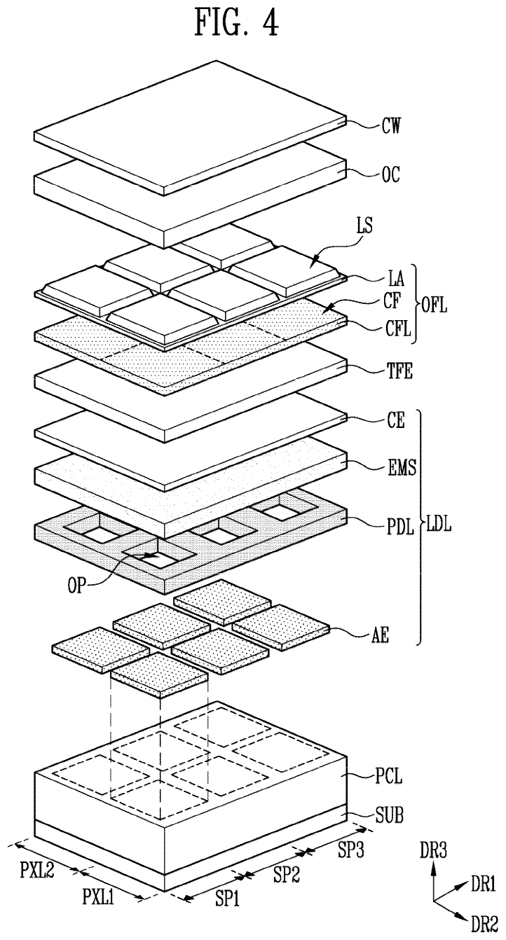

FIG. 4 is an exploded schematic perspective view illustrating a portion of the display panel shown in FIG. 3. In FIG. 4, for clarity and brevity, a portion of the display panel DP corresponding to two pixels PXL1 and PXL2 among the pixels shown in FIG. 3 is schematically illustrated. Portions of the display panel DP corresponding to other pixels may be configured identically.

Referring to FIGS. 3 and 4, each of first and second pixels PXL1 and PXL2 may include first, second, and third sub-pixels SP1, SP2, and SP3. However, embodiments are not limited thereto. For example, each of the first and second pixels PXL1 and PXL2 may include four sub-pixels or include two sub-pixels.

In FIG. 4, the first to third sub-pixels SP1, SP2, and SP3 are illustrated as having quadrangular shapes when viewed in a third direction DR3 intersecting the first and second directions DR1 and DR2 and as being of the same size. However, embodiments are not limited to these shapes. The first to third sub-pixels SP1, SP2, and SP3 may be modified to have various other shapes.

The display panel DP may include a substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be derived from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see FIG. 2) of each of the first to third sub-pixels SP1 to SP3. The sub-pixel circuit SPC may include transistors and one or more capacitors. Each transistor may include a semiconductor portion with a source region, a drain region, a channel region, and a gate electrode overlapping the semiconductor portion. In embodiments, in the case where the substrate SUB is a silicon substrate, the semiconductor portion may be included in the substrate SUB, and the gate electrode may be included as a conductive pattern of the pixel circuit layer PCL. In embodiments, in the case where the substrate SUB is a glass substrate or PI substrate, both the semiconductor portion and the gate electrode may be included in the pixel circuit layer PCL. Each capacitor may include electrodes spaced apart from each other. For example, each capacitor may include electrodes spaced apart from each other, either on a plane defined by the first and second directions DR1 and DR2, or along the third direction DR3 with an insulating layer interposed therebetween.

The lines of the pixel circuit layer PCL may include signal lines, e.g., gate lines, emission control lines, data lines, and the like, which are connected to each of the first to third sub-pixels SP1, SP2, and SP3. The lines may further include a line connected to the first power voltage node VDDN as shown in FIG. 2. The lines may further include a line connected to the second power voltage node VSSN as shown in FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL and in contact with its circuit elements. The anode electrodes AE may include an opaque conductive material capable of reflecting light, though embodiments are not limited to this material.

The pixel defining layer PDL may be disposed over the anode electrodes AE and include an opening OP that exposes a portion of each of the anode electrodes AE. The opening OP of the pixel defining layer PDL may correspond to an emission area for each of the first to third sub-pixels SP1 to SP3.

In embodiments, the pixel defining layer PDL may include an inorganic material. The pixel defining layer PDL may include multiple stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer that generates light, an electron transport layer that transports electrons, a hole transport layer that transports holes, and the like.

In embodiments, the light emitting structure EMS fills the opening OP of the pixel defining layer PDL and may be cover the top of the pixel defining layer PDL. This means that the light emitting structure EMS may extend across all first to third sub-pixels SP1, SP2, and SP3. At least some layers of the light emitting structure EMS may be cut or bent at boundaries between the first to third sub-pixels SP1 to SP3. However, embodiments are not limited thereto. For example, portions of the light emitting structure EMS corresponding to the first to third sub-pixels SP1 to SP3 may be separated from each other and individually placed in each opening OP of the pixel defining layer PDL.

The cathode electrode CE may be disposed on the light emitting structure EMS. The cathode electrode CE may extend across the first to third sub-pixels SP1 to SP3, thus serving as a common electrode for the first to third sub-pixels SP1 to SP3.

The cathode electrode CE may be a thin metal layer with a thickness that allows light emitted from the light emitting structure EMS to transmit through. The cathode electrode CE may be formed of a metal material to have a relatively thin thickness or may be formed of a transparent conductive material. In embodiments, the cathode electrode CE may include at least one of various transparent conductive materials, such as indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or mixtures thereof. However, the material of the cathode electrode CE is not limited thereto.

It may be understood that each light emitting element LD (see FIG. 2) may include any of the anode electrodes AE, a portion of the light emitting structure EMS that overlaps therewith, and a portion of the cathode electrode CE that overlaps therewith. For example, each light emitting element of the first to third sub-pixels SP1 to SP3 may include one anode electrode AE, a portion of the light emitting structure EMS that overlaps therewith, and a portion of the cathode electrode CE that overlaps therewith. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons transition from an excited state to a ground state. A luminance of the light may be determined by an amount of current flowing through the light emitting layer. A wavelength band of the generated light may be determined by a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may prevent oxygen and/or moisture from infiltrating into the light emitting element layer LDL. In embodiments, the encapsulation layer TFE may include a structure in which at least one inorganic layer and at least one organic layer are alternately stacked. For example, the inorganic layer may include materials such as silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency, the encapsulation layer TFE may further include a thin film including aluminum oxide (AlOₓ). The thin film may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process, although other processes may also be used. The encapsulation layer TFE may further include a thin film formed of various materials suitable for enhancing encapsulation efficiency.

The optical functional layer OFL may be disposed on the encapsulation layer TFE. The optical functional layer OFL may include a filter layer CFL and a lens array LA.

The filter layer CFL may be disposed between the encapsulation layer TFE and the lens array LA. The filter layer CFL may filter light emitted from the light emitting structure EMS, selectively outputting light of a wavelength band or a color corresponding to each sub-pixel SP. The filter layer CFL may include filters CF that correspond to the first to third sub-pixels SP1 to SP3. Each of the filters CF may allow light having a wavelength band corresponding to each sub-pixel to pass therethrough. For example, a filter corresponding to the first sub-pixel SP1 may allow light of a red color to pass therethrough, a filter corresponding to the second sub-pixel SP2 may allow light of a green color to pass therethrough, and a filter corresponding to the third sub-pixel SP3 may allow light of a blue color to pass therethrough. Depending on the light emitted from the light emitting structure EMS in each sub-pixel SP, some of the filters CF may be omitted.

The lens array LA may be disposed on the filter layer CFL. The lens array LA may include lenses LS corresponding respectively to the first to third sub-pixels SP1 to SP3. Each of the lenses LS may output light emitted from the light emitting structure EMS along an intended path, improving light emission efficiency. The lens array LA may have a relatively high refractive index. For example, the lens array LA may have a refractive index higher than a refractive index of the overcoat layer OC. In embodiments, the lenses LS may include an organic material, such as an acryl-based material, although other materials may also be used.

In embodiments, some of the filters CF of the filter layer CFL and some of the lenses LS of the lens array LS may be shifted in a direction parallel to a plane defined by the first and second directions DR1 and DR2, relative to the openings OP of the pixel defining layer PDL. Specifically, in a central area of the display area DA, the center of a filter and the center of a lens may align or overlap the center of a corresponding opening OP of the pixel defining layer PDL. For example, in the central area of the display area DA, the opening OP of the pixel defining layer PDL may completely overlap the corresponding filter of the filter layer CFL and the corresponding lens of the lens array LA. In an area of the display area DA adjacent to the non-display area NDA, the center of a filter and the center of a lens may be shifted in a planar direction relative to the center of the corresponding opening OP of the pixel defining layer PDL. For example, in the area of the display area DA adjacent to the non-display area NDA, the opening OP of the pixel defining layer PDL may partially overlap the corresponding filter of the filter layer CFL and the corresponding lens of the lens array LA. Accordingly, in the center of the display area DA, light emitted from the light emitting structure EMS can be effectively output in a normal direction to the display surface. In an outer portion of the display area DA, light emitted from the light emitting structure EMS can be effectively output at a selected inclined angle relative to the normal direction of the display surface.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may protect lower layers thereof. The cover window CW may have a refractive index higher than the refractive index of the overcoat layer OC. The cover window CW may include glass, but embodiments are not limited thereto. For example, the cover window CW may be an encapsulation glass that protects components disposed thereunder. In other embodiments, the cover window CW may be omitted.

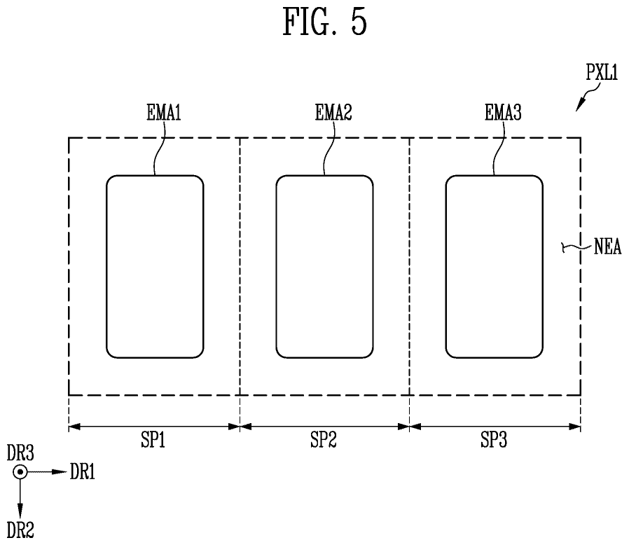

FIG. 5 is a schematic plan view illustrating an embodiment of any of the pixels shown in FIG. 4. In FIG. 5, for clarity and brevity, the first pixel PXL1 among the pixels shown in FIG. 4 is schematically illustrated. The other pixels may be substantially identical to the first pixel PXL1.

Referring to FIGS. 4 and 5, the first pixel PXL1 may include first to third sub-pixels SP1 to SP3 arranged along the first direction DR1.

The first sub-pixel SP1 may include a first emission area EMA1 and a non-emission area NEA surrounding the first emission area EMA1. Similarly, the second sub-pixel SP2 may include a second emission area EMA2 and the non-emission area NEA surrounding the second emission area EMA2. The third sub-pixel SP3 may include a third emission area EMA3 and the non-emission area NEA surrounding the third emission area EMA3.

The first emission area EMA1 may be an area in which light is emitted from a portion of the light emitting structure EMS (see FIG. 4) associated with the first sub-pixel SP1. The second emission area EMA2 may be an area in which light is emitted from a portion of the light emitting structure EMS associated with the second sub-pixel SP2. The third emission area EMA3 may be an area in which light is emitted from a portion of the light emitting structure EMS associated with the third sub-pixel SP3. As described with reference to FIG. 4, each emission area may be understood as an opening in the pixel defining layer PDL corresponding to each of the first to third sub-pixels SP1 to SP3.

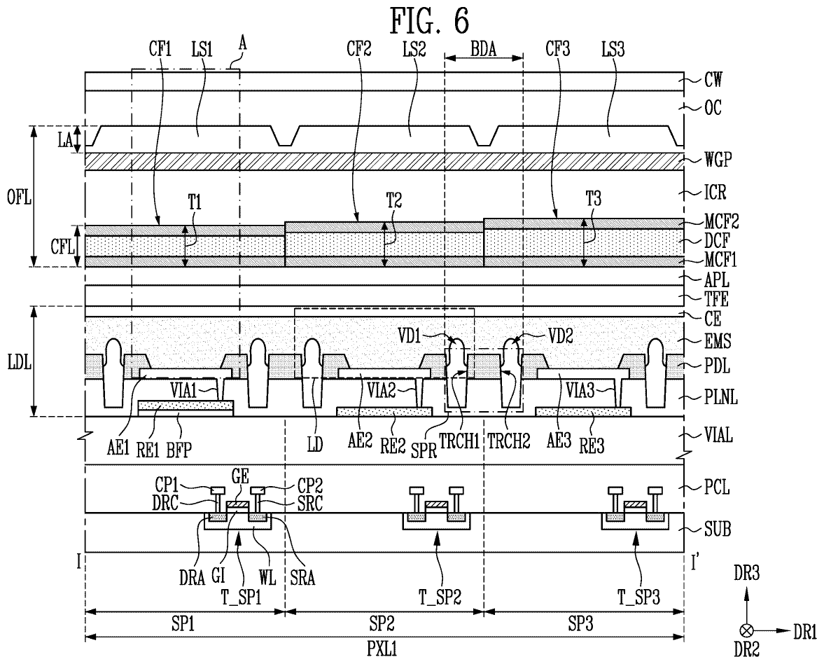

FIG. 6 is a schematic sectional view taken along line I-I′ shown in FIG. 3.

Referring to FIG. 6, a substrate SUB and a pixel circuit layer PCL disposed on the substrate SUB may be provided.

The substrate SUB may include a silicon wafer formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any of transistors included in a sub-pixel circuit SPC (see FIG. 2) of the first sub-pixel SP1, the transistor T_SP2 of the second sub-pixel SP2 may be any of transistors included in a sub-pixel circuit SPC of the second sub-pixel SP2, and the transistor T_SP3 of the third sub-pixel SP3 may be any of transistors included in a sub-pixel circuit SPC of the third sub-pixel SP3. In FIG. 6, for clarity and brevity, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be disposed in the substrate SUB. A well WL formed by an ion implantation process may be disposed in the substrate SUB, and the source region SRA and the drain region DRA may be disposed in the well WL, spaced apart from each other. A region between the source region SRA and the drain region DRA in the well WL may define a channel region.

The gate electrode GE may overlap the channel region between the source region SRA and the drain region DRA, and be disposed in the pixel circuit layer PCL. The gate electrode GE may be spaced apart from the well WL or the channel region by an insulating material such as a gate insulating layer GI. The gate electrode GE may include a conductive material.

Layers included in the pixel circuit layer PCL may include insulating layers and conductive patterns disposed between the insulating layers, and the conductive patterns may include first and second conductive patterns CP1 and CP2. The first conductive pattern CP1 may connect electrically to the drain region DRA via a drain connection portion DRC penetrating one or more insulating layers. Similarly, the second conductive pattern CP2 may connect electrically to the source region SRA via a source connection portion SRC penetrating one or more insulating layers.

The gate electrode GE and the first and second conductive patterns CP1 and CP2 may connect other circuit elements and/or lines, providing the transistor T_SP1 of the first sub-pixel SP1 as any of the transistors of the first sub-pixel SP1.

Each of the transistor T_SP2 of the second sub-pixel SP2 and the transistor T_SP3 of the third sub-pixel SP3 may be substantially identical to the transistor T_SP1 of the first sub-pixel SP1.

As such, the substrate SUB and/or the pixel circuit layer PCL may include circuit elements of each of the first to third sub-pixels SP1 to SP3.

A via layer VIAL may be disposed on the pixel circuit layer PCL. The via layer VIAL covers the pixel circuit layer PCL, and may provide a flat surface, planarizing step differences on the pixel circuit layer PCL. The via layer VIAL may include at least one of silicon oxide (SiOₓ), silicon nitride (SiNₓ), and silicon carbon nitride (SiCN), but embodiments are not limited thereto.

A light emitting element layer LDL may be disposed on the via layer VIAL. The light emitting element layer LDL may include first to third reflective electrodes RE1, RE2, and RE3, a planarization layer PLNL, first to third anode electrodes AE1 to AE3, a pixel defining layer PDL, a light emitting structure EMS, and a cathode electrode CE.

The first to third reflective electrodes RE1 to RE3 may be disposed on the via layer VIAL in the first to third sub-pixels SP1 to SP3, respectively. Each of the first to third reflective electrodes RE1 to RE3 may contact a circuit element disposed in the pixel circuit layer PCL through a via penetrating the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a light-reflective metal material, including, but not limited to, aluminum (Al), silver (Ag), magnesium (Mg), platinum (Pt), palladium (Pd), gold (Au), nickel (Ni), neodymium (Nd), iridium (Ir), chromium (Cr), titanium (Ti), and their alloys.

In embodiments, a connection electrode may be disposed at the bottom of each of the first to third reflective electrodes RE1 to RE3 to improve an electrical connection between a corresponding reflective electrode and a circuit element of the pixel circuit layer PCL. The connection electrode may have a multi-layer structure. The multi-layer structure may include, but is not limited to, titanium (Ti), titanium nitride (TiN), tantalum nitride (TaN), and the like. In embodiments, a corresponding reflective electrode may be located between multiple layers of the connection electrode.

A buffer pattern BFP may be disposed beneath at least one of the first to third reflective electrodes RE1 to RE3A. The buffer pattern BFP may include an inorganic material such as silicon carbon nitride, but embodiments are not limited thereto. By incorporating the buffer pattern BFP, a height of the corresponding reflective electrode in a third direction DR3 may be controlled. For example, the buffer pattern BFP may be disposed between the first reflective electrode RE1 and the via layer VIAL to adjust a height of the first reflective electrode RE1.

The first to third reflective electrodes RE1 to RE3 may act as full mirrors, while the cathode electrode CE may function as a half mirror. Light emitted from a light emitting layer of the light emitting structure EMS may be amplified through multiple reflections between a corresponding reflective electrode and the cathode electrode CE, and the amplified light may be output through the cathode electrode CE. Thus, a distance between each reflective electrode and the cathode electrode CE may define a resonance distance of light emitted from the light emitting layer of the corresponding light emitting structure EMS.

The buffer pattern BFP may enable the first sub-pixel SP1 to have a resonance distance shorter than a resonance distance of other sub-pixels. The adjusted resonance distance enables effective and efficient amplification of light in a specific wavelength range (e.g., red color). Accordingly, the first sub-pixel SP1 can effectively and efficiently output light in the corresponding wavelength range.

FIG. 6 illustrates that the buffer pattern BFP is provided to the first sub-pixel SP1 but not to the second and third sub-pixels SP2 and SP3. However, embodiments are not limited thereto. The buffer pattern may also be incorporated into at least one of the second and/or third sub-pixels SP2 and SP3 to adjust their resonance distances. For example, the first to third sub-pixels SP1 to SP3 may correspond to red, green, and blue, respectively. A distance between the first reflective electrode RE1 and the cathode electrode CE may be shorter than a distance between the second reflective electrode RE2 and the cathode electrode CE, and the distance between the second reflective electrode RE2 and the cathode electrode CE may, in turn, be shorter than a distance between the third reflective electrode RE3 and the cathode electrode CE.

The planarization layer PLNL may be disposed on the via layer VIAL and the first to third reflective electrodes RE1 to RE3 to planarize step differences among the first to third reflective electrodes RE1 to RE3. The planarization layer PLNL covers the first to third reflective electrodes RE1 to RE3 and the via layer VIAL, providing a flat surface. In embodiments, the planarization layer PLNL may be omitted.

The first to third anode electrodes AE1 to AE3, respectively overlapping the first to third reflective electrodes RE1 to RE3, may be disposed on the planarization layer PLNL. The shapes of the first to third anode electrodes AE1 to AE3 may be similar to those of the first to third emission area EMA1 to EMA3 shown in FIG. 5 when viewed in the third direction DR3. The first to third anode electrodes AE1 to AE3 may be electrically connected to the first to third reflective electrodes RE1 to RE3, respectively. The first anode electrode AE1 may be electrically connected to the first reflective electrode RE1 through a first via VIA1 penetrating the planarization layer PLNL. Similarly, the second anode electrode AE2 may be electrically connected to the second reflective electrode RE2 through a second via VIA2 penetrating the planarization layer PLNL, and the third anode electrode AE3 may be electrically connected to the third reflective electrode RE3 through a third via VIA3 penetrating the planarization layer PLNL.

In embodiments, the first to third anode electrodes AE1 to AE3 may include at least one of transparent conductive materials, such as indium tin oxide (ITO), indium zinc oxide (IZO), zinc oxide (ZnOx), indium gallium zinc oxide (IGZO), and indium tin zinc oxide (ITZO). However, the material of the first to third anode electrodes AE1 to AE3 is not limited thereto. For example, the first to third anode electrodes AE1 to AE3 may include titanium nitride.

In embodiments, insulating layers may be included to adjust a height of at least one of the first to third anode electrodes AE1 to AE3. The insulating layers may be disposed between at least one of the first to third anode electrodes AE1 to AE3 and their corresponding reflective electrodes. The planarization layer PLNL and/or the buffer pattern BFP may be omitted as needed. For example, with the first to third sub-pixels SP1 to SP3 corresponding to red, green, and blue, respectively, a distance between the first anode electrode AE1 and the cathode electrode CE may be shorter than a distance between the second anode electrode AE2 and the cathode electrode CE, which in turn may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include an opening OP exposing a portion of each of the first to third anode electrodes AE1 to AE3, thereby defining an emission area of each of the first to third sub-pixels SP1 to SP3. Thus, the pixel defining layer PDL may define the first to third emission areas EMA1 to EMA3 shown in FIG. 5 while occupying the non-emission area NEA shown in FIG. 5.

In embodiments, the pixel defining layer PDL may include multiple inorganic insulating layers. Each of the inorganic insulating layers may include at least one of silicon oxide (SiOₓ) and silicon nitride (SiNₓ). For example, the pixel defining layer PDL may include first to third inorganic insulating layers sequentially stacked, with the first to third inorganic insulating layers including silicon nitride, silicon oxide, and silicon nitride, respectively. However, embodiments are not limited thereto. The first to third inorganic insulating layers may have a stepped section in an area adjacent to the opening OP.

A separator SPR may be provided in a boundary area BDA between adjacent sub-pixels. For example, the separator SPR may be positioned in each of boundary areas between the sub-pixels SP shown in FIG. 3.

The separator SPR may create a discontinuity in the light emitting structure EMS within the boundary area BDA. For example, due to the presence of the separator SPR, the light emitting structure EMS may be cut or bent in the boundary area BDA.

The separator SPR may be provided in or on the pixel defining layer PDL. The pixel defining layer PDL may include one or more trenches TRCH1 and TRCH2 functioning as the separator SPR. In embodiments, as shown in FIG. 6, the one or more trenches TRCH1 and TRCH2 may penetrate the pixel defining layer PDL and partially penetrate the via layer VIAL. In other embodiments, one or more trenches TRCH1 and TRCH2 may penetrate the pixel defining layer PDL and the planarization layer PLNL, partially penetrating the via layer VIAL. In other embodiments, one or more trenches TRCH1 and TRCH2 may at least partially penetrate the planarization layer PLNL and/or via layer VIAL, with a portion of the pixel defining layer PDL disposed within the one or more trenches TRCH1 and TRCH2.

FIG. 6 illustrates that two trenches TRCH1 and TRCH2 are provided in the boundary area BDA. However, embodiments are not limited thereto. For example, the pixel defining layer PDL may include one trench in the boundary area BDA, or the pixel defining layer PDL may include three or more trenches in the boundary area BDA.

Due to first and second trenches TRCH1 and TRCH2, discontinuities such as a first void VD1 and a second void VD2 may form in the light emitting structure EMS in the boundary area BDA. Some of the layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1, SP2, and SP3, may be at least partially separated from each other.

In FIG. 6, the first and second voids VD1 and VD2 are depicted in the light emitting structure EMS in the boundary area BDA. However, this is illustrative, and embodiments are not limited thereto. For example, a concave-shaped valley may be formed in the light emitting structure EMS in the boundary area BDA. The discontinuities formed in the light emitting structure EMS may vary according to shapes of the first and second trenches TRCH1 and TRCH2.

In embodiments, the light emitting structure EMS may be formed through a process such as vacuum deposition or inkjet printing. The same materials used in the light emitting structure EMS may be present on bottom surfaces adjacent to the via layer VIAL among the first and second trenches TRCH1 and TRCH2.

The separator SPR may be modified in various ways to create a discontinuity in the light emitting structure EMS in the boundary area BDA. In embodiments, inorganic insulating patterns additionally stacked on the pixel defining layer PDL, without the first and second trenches TRCH1 and TRCH2, may be provided in the boundary area BDA. A width of an inorganic insulating pattern at an uppermost portion among the additionally stacked inorganic insulating patterns may be greater than a width of an inorganic insulating pattern disposed immediately under the inorganic insulating pattern at the uppermost portion. For example, in the boundary area BDA, first to third inorganic insulating patterns are sequentially stacked from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA. Depending on the shape of the pixel defining layer PDL, the multiple layers included in the light emitting structure EMS may be partially cut or bent in the boundary area BDA.

The light emitting structure EMS may be disposed on the anode electrodes AE exposed by the openings OP in the pixel defining layer PDL. The light emitting structure EMS fills the openings OP in the pixel defining layer PDL, and may be uniformly distributed across the first to third sub-pixels SP1 to SP3. As described above, the light emitting structure EMS may be at least partially cut or bent by the separator SPR in the boundary area BDA. Accordingly, during an operation of the display panel DP, current leakage between the first to third sub-pixels SP1 to SP3 through layers included in the light emitting structure EMS can be minimized. Thus, first to third light emitting elements LD1 to LD3 can operate with relatively high reliability.

The cathode electrode CE may be disposed over the light emitting structure EMS. The cathode electrode CE may be commonly provided in the first to third sub-pixels SP1 to SP3. The cathode electrode CE may function as a half mirror, allowing light emitted from the light emitting structure EMS to be partially transmitted therethrough and partially reflected therefrom.

The first anode electrode AE1, a portion of the light emitting structure EMS overlapping the first anode electrode AE1, and a portion of the cathode electrode CE overlapping the first anode electrode AE1 may form a first light emitting element. Similarly, the second anode electrode AE2, a portion of the light emitting structure EMS overlapping the second anode electrode AE2, and a portion of the cathode electrode CE overlapping the second anode electrode AE2 may form a second light emitting element, while the third anode electrode AE3, a portion of the light emitting structure EMS overlapping the third anode electrode AE3, and a portion of the cathode electrode CE overlapping the third anode electrode AE3 may form a third light emitting element.

An encapsulation layer TFE may be disposed on the cathode electrode CE to prevent oxygen and/or moisture from infiltrating into the light emitting element layer LDL.

An optical functional layer OFL may be disposed on the encapsulation layer TFE. In embodiments, the optical functional layer OFL may be attached to the encapsulation layer TFE through an adhesive layer APL. For example, the optical functional layer OFL may be manufactured separately and then attached to the encapsulation layer TFE with the adhesive layer APL. The adhesive layer APL may also help protect the underlying layers, including the encapsulation layer TFE.

The optical functional layer OFL may include a filter layer CFL and a lens array LA. The filter layer CFL may include first to third filters CF1 to CF3, corresponding respectively to the first to third sub-pixels SP1 to SP3. The first to third filters CF1 to CF3 selectively transmit or reflect light of various wavelengths emitted from the light emitting structure EMS by generating a multiple interference phenomenon, thereby improving light efficiency.

The first filter CF1 may overlap the first light emitting element that emits light of a first color. The second filter CF2 may overlap the second light emitting element that emits light of a second color. The third filter CF3 may overlap the third light emitting element that emits light of a third color. The first to third colors may be red, green, and blue, respectively, though other colors are possible.

In embodiments, each of the first to third filters CF1 to CF3 may include a first metal layer MCF1, a second metal layer MCF2, and a dielectric layer DCF disposed between the first and second metal layers MCF1 and MCF2. This configuration helps secure a high color agreement rate in the case where each of the first to third filters CF1 to CF3 is combined with a light spectrum emitted from the light emitting structure EMS. For example, the first to third filters CF1 to CF3 may achieve a high color agreement rate in the case where their transmittances for each wavelength align with an intensity of emitted light.

The first and second metal layers MCF1 and MCF2 may include a metal with a reflectivity in a range of about 10% to about 99%. For example, the metal may include a single material, such as silver (Ag), aluminum (Al), copper (Cu), gold (Au), chromium (Cr), molybdenum (Mo), magnesium (Mg), nickel, lanthanum (La), or palladium (Pd). They may also include a compound, such as silver-magnesium ally (AgMg), aluminum-nickel-lanthanum (AlNiLa), or APC (AgPdCu), though other materials are possible.

The dielectric layer DCF may have light transmissivity, and include a material that may adjust a phase. For example, the dielectric layer DCF may include an organic material, such as acrylic resin, epoxy resin, phenolic resin, polyamide resin, polyimide resin, polyester resin, polyphenylenesulfide resin, or benzocyclobutene (BCB), as well as an inorganic compound, such as oxides, nitrides, carbides, phosphides, halides, sulfides, tellurides, or selenides. However, the kind of the material included in the dielectric layer DCF is not limited thereto. For example, the dielectric layer DCF may have a refractive index in a range of about 0 to about 3, an absorption coefficient in a range of about 0 to about 3, or a dielectric constant in a range of about 1 to about 10.

The first to third filters CF1 to CF3 may have different thicknesses. Each of the first to third filters CF1 to CF3 may have a thicknesses T1 to T3 of less than or equal to about 0.2 μm. Dielectric layers DCF of the first to third filters CF1 to CF3 may have different thicknesses. Adjusting the material and thickness of each of the first to third filters CF1 to CF3 allows for fine-tuning of the transmittance and reflectivity of each of the first to third filters CF1 to CF3, optimizing the emitted light spectrum from the light emitting structure EMS. For example, the first filter CF1 overlapping the first light emitting element that emits light of red may include a first metal layer MCF1 of about 50 nm, a dielectric layer DCF of about 70 nm, and a second metal layer MCF2 of about 50 nm. The second filter CF2 overlapping the second light emitting element that emits light of green may include a first metal layer MCF1 of about 50 nm, a dielectric layer DCF of about 95 nm, and a second metal layer MCF2 of about 50 nm. The third filter CF3 overlapping the third light emitting element that emits light of blue may include a first metal layer MCF1 of about 50 nm, a dielectric layer DCF of about 125 nm, and a second metal layer MCF2 of about 50 nm. A thickness of the first filter CF1 may be less than a thickness of the second filter CF2, and a thickness of the third filter CF3 may be greater than the thickness of the second filter CF2. However, the thicknesses T1 to T3 of the first to third filters CF1 to CF3 are not limited to these specific values.

The optical functional layer OFL may include a polarizing layer WGP disposed above the filter layer CFL and a phase retardation layer ICR disposed between the filter layer CFL and the polarizing layer WGP. In an embodiment, the polarizing layer WGP may include a linear polarizer that transmits light linearly polarized in one direction as it transmits through the first to third filters CF1 to CF3. The phase retardation layer ICR may include a phase retarder that shifts the phase of light by λ/4 as it is transmitted through the first to third filters CF1 to CF3. For example, the phase retardation layer ICR may have optical anisotropy, and change a polarization state of light incident onto the phase retardation layer ICR. The light entering the phase retardation layer ICR may be converted from a circular polarization state to a linear polarization state.

Each of the first to third filters CF1 to CF3, including the first and second metal layers MCF1 and MCF2 and the dielectric layer DCF, may have a thickness of less than or equal to about 0.2 μm. Accordingly, reducing the thickness of each of the first to third filters CF1 to CF3 decreases the distance between the first to third anode electrodes AE1 to AE3 and the polarizing layer WGP, thereby improving the recycling efficiency of the display panel DP (see FIG. 3). As the recycling efficiency increases, luminance variation between the center and the periphery of the display area DA is reduced or minimized, thereby improving the display quality.

The lens array LA may be disposed on the filter layer CFL. The lens array LA may include first to third lenses LS1 to LS3 corresponding respectively to the first to third sub-pixels SP1 to SP3. The first to third lenses LS1 to LS3 may direct the lights emitted from the first to third light emitting layers along intended paths, thereby improving light emission efficiency.

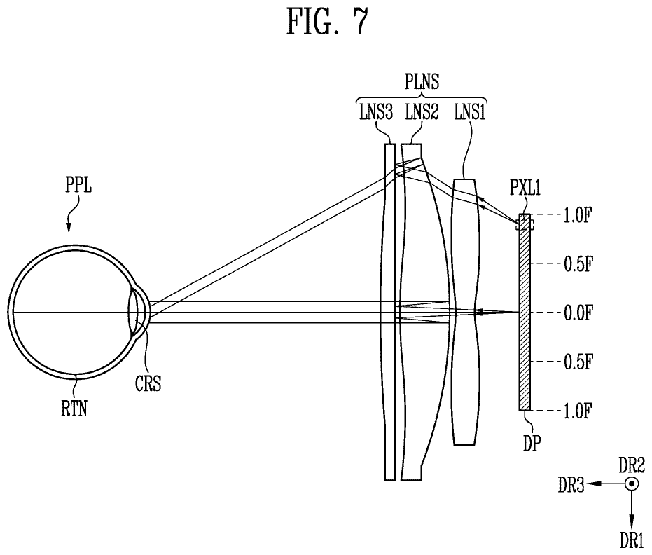

FIG. 7 is a schematic sectional view illustrating an embodiment of light emitted according to a position of the display panel shown in FIG. 1.

Referring to FIG. 7, the display device DD in accordance with the embodiment of the disclosure may be used together with a pancake lens PLNS located in front of the display panel DP. The pancake lens PLNS may be located between the display panel DP and an eye PPL of a user, allowing light emitted from the display panel DP to be viewed more widely, thereby enhancing immersion and three-dimensional effect.

The pancake lens PLNS may direct light emitted from the display area DA (see FIG. 3) of the display panel DP to converge on a crystalline lens CRS of the eye PPL, allowing the light to reach a retina RTN after transmitting through the crystalline lens CRS. The pancake lens PLNS enables the user to clearly recognize images on the display area DA even when the display panel DP is close to the eye PPL of the user.

The pancake lens PLNS may include multiple curved lenses LNS1 to LNS3. In an example, a first curved lens LNS1 may be located adjacent to the display panel DP. The first curved lens LNS1 may adjust a path of light emitted from the display panel DP toward a second curved lens LNS2. The first curved lens LNS1 may be disposed between the display panel DP and the second curved lens LNS2. The second curved lens LNS2 may be located in front of the first curved lens LNS1 in the third direction DR3. The second curved lens LNS2 may have a diameter greater than a diameter of the first curved lens LNS1. A third curved lens LNS3 may be located in front of the first and second curved lenses LNS1 and LNS2 in the third direction DR3, and be located closest to the eye PPL of the user. The third curved lens LNS3 may include a front surface facing the eye PPL of the user and a rear surface facing the second curved lens LNS2.

Light emitted from the display panel DP may be refracted as it transmits through the first curved lens LNS1. The light transmitted through the first curved lens LNS1 may be further refracted by the second curved lens LNS2. The light transmitted through the second curved lens LNS2 may be reflected off the rear surface of the third curved lens LNS3 back toward the second curved lens LNS2. It may then be reflected again off a rear surface of the second curved lens LNS2, directing it toward the third curved lens LNS3. The light passing through the third curved lens LNS3, where it is refracted again before reaching the eye PPL of the user. The light transmitted through the third curved lens LNS3 may be directed toward the eye PPL of the user. However, this configuration is given as an example of the pancake lens PLNS, and the number, shape or arrangement of lenses is not limited thereto.

The display panel DP may include a display area DA (see FIG. 3) and a non-display area NDA (see FIG. 3) surrounding the display area DA. In embodiments, the display area DA may become closer to 0.0 F near its center, and become closer to 1.0 F toward the periphery. For example, in the case where the display area DA corresponds to a middle position between the center of the display area DA and the non-display area NDA, the position of the display area DA may be defined as 0.5 F.

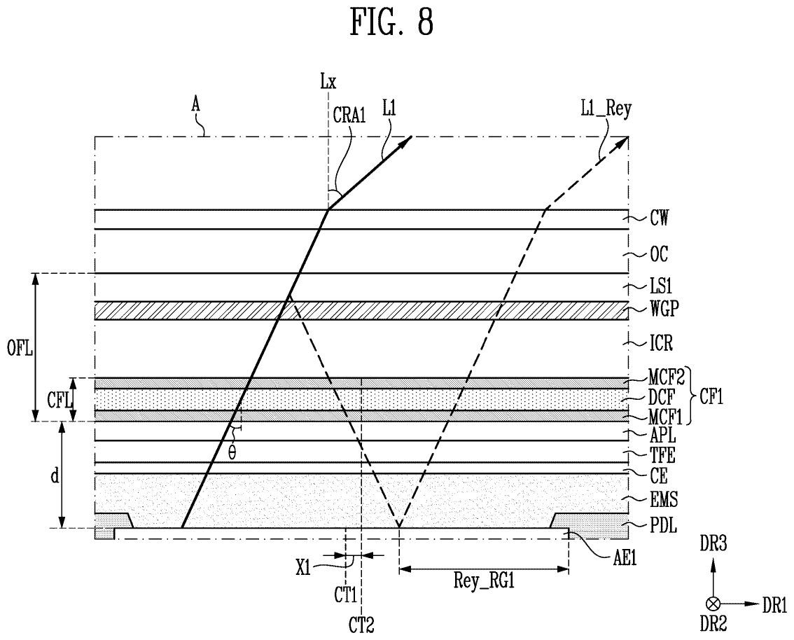

As the position of the display area DA becomes closer to 1.0 F, a chief ray angle CRA1 (see FIG. 8) may increase. Light emitted at 1.0 F may still reach the eye PPL of the user through the pancake lens PLNS. In an embodiment of the disclosure, the display area DA may be divided into positions ranging from 0.0 F to 1.0 F, and a chief ray angle may be selected for each position. The selected chief ray angle may vary depending on a design of the pancake lens PLNS.

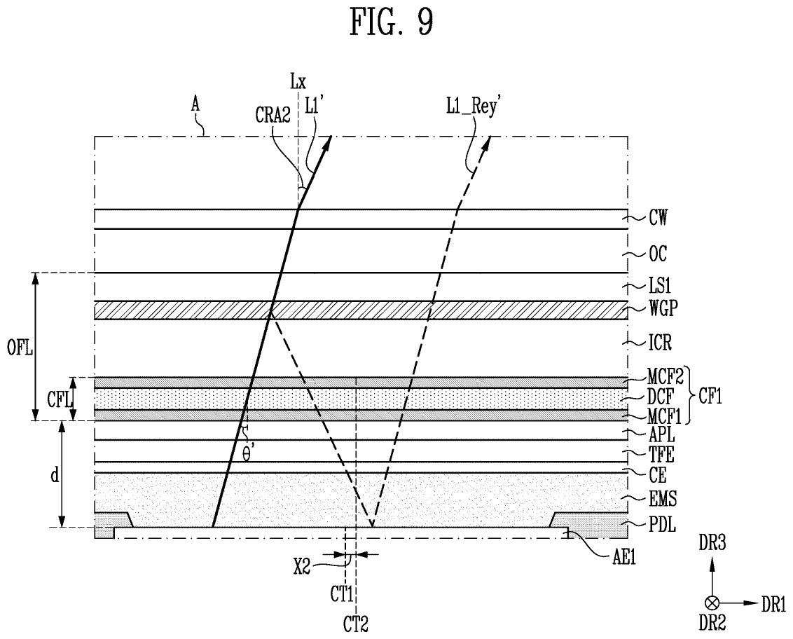

FIGS. 8 and 9 are enlarged schematic views illustrating portion A shown in FIG. 6.

Referring to FIG. 8, a chief ray angle CRA1 may refer to an angle formed by light L1 transmitted through the cover window CW disposed on a front surface of the display panel DP and a vertical optical axis Lx.

Referring to FIGS. 3 and 8, the first pixel PXL1 adjacent to the non-display area NDA may have a chief ray angle CRA1 greater than a chief ray angle CRA1 of a third pixel PXL3, which is adjacent to the center of the display area DA. For example, in the case where the position of the first pixel PXL1 corresponds to 0.9 F in the display area DA, the chief ray angle CRA1 of the first pixel PXL1 may be 23.751 degrees. However, the corresponding angle is described as an example, and the disclosure is not limited thereto. Hereinafter, the first sub-pixel SP1 of the first pixel PXL1 will be described as an example, but the second and third sub-pixels SP2 and SP3 of the first pixel PXL1 may be substantially identical to the first sub-pixel SP1 of the first pixel PXL1.

In embodiments, a center of the first light emitting element included in the first sub-pixel SP1 of the first pixel PXL1 may align with a center CT1 of the first anode electrode AE. A center CT2 of the first filter CF1 overlapping the first light emitting element may be shifted by a first distance X1 in the first direction DR1 from the center CT1 of the first anode electrode AE1. For example, in the case where the chief ray angle CRA1 of the first pixel PXL1 is 23.751 degrees, the first distance X1 shifted in the first direction DR1 between the center CT2 of the first filter CF1 and the center CT1 of the first anode electrode AE1 may be about 0.62 μm. While FIG. 8 illustrates the shift in the first direction DR1, the disclosure is not limited thereto. For example, the center CT2 of the first filter CF1 may also be shifted in the second direction DR2, which intersects the first direction DR1, from the center CT1 of the first anode electrode AE1.

Specifically, a distance X by which the center CT2 of the first filter CF1 is shifted may be calculated by Equation 1.

$$x = d \cdot tan θ \qquad Equation 1$$

$${n}_{eff} \cdot sin θ = sin ( C R A )$$

Here, d may represent a distance between the first anode electrode AE1 and the first filter CF1, and n_{eff} may denote an average refractive index of a medium disposed between the first anode electrode AE1 and the first filter CF1. CRA may refer to a chief ray angle selected according to a position of the display area DA, and θ may be an angle calculated from the chief ray angle according to Snell's law.

In embodiments, the first filter CF1 has thicknesses of less than or equal to about 0.2 μm, including the first and second metal layers MCF1 and MCF2 and the dielectric layer DCF, allowing a distance between the first anode electrode AE1 and the polarizing layer WGP to be reduced. The polarizing layer WGP may function to recycle at least a portion L1_Rey of the light L1 provided from the first anode electrode AE1 through total reflection, thereby improving light efficiency. As the distance between the first anode electrode AE1 and the polarizing layer WGP is reduced, an area Rey_RG1 in which light is totally reflected in the polarizing layer WGP for recycling may increase. The light output efficiency of the light emitted from the light emitting element may improve as the recycled area Rey_RG1 increases.

Referring to FIGS. 3 and 9, the third pixel PXL3, which is adjacent to the center of the display area DA on the display panel DP, may have a chief ray angle CRA2 smaller than the chief ray angle CRA1 of the first pixel PXL1. For example, in the case where the position of the third pixel PXL3 corresponds to 0.5 F in the display area DA, the chief ray angle CRA2 of the third pixel PXL3 may be approximately 12.027 degrees. However, the corresponding angle is described as an example, and the disclosure is not limited thereto. Hereinafter, a first sub-pixel SP1 of the third pixel PXL3 will be described as an example, but the second and third sub-pixels SP2 and SP3 of the third pixel PXL3 may be substantially identical to the first sub-pixel SP1 of the third pixel PXL3.

In embodiments, a center of a first light emitting element included in the first sub-pixel SP1 of the third pixel PXL3 may align with the center CT1 of the first anode electrode AE1. The center CT2 of the first filter CF1 overlapping the first light emitting element may be shifted by a second distance X2 in the first direction DR1 from the center CT1 of the first anode electrode AE1. For example, in the case where the chief ray angle CRA2 of the third pixel PXL3 is 12.027 degrees, the second distance X2 shifted in the first direction DR1 between the center CT2 of the first filter CF1 and the center CT1 of the first anode electrode AE may be about 0.31 μm. While FIG. 9 illustrates the shift in the first direction DR1, the disclosure is not limited thereto. For example, the center CT2 of the first filter CF1 may also be shifted in the second direction DR2, which intersects the first direction DR1, from the center CT1 of the first anode electrode AE1.

As a pixel becomes closer to the center of the display area DA, a distance by which the center CT2 of the first filter CF1 is shifted from the center CT1 of the first anode electrode AE1 may decrease. On the other hand, as the pixel becomes farther from the center of the display area DA, the distance by which the center CT2 of the first filter CF1 is shifted from the center CT1 of the first anode electrode AE1 may increase. Thus, the distance between the center CT2 of the first filter CF1 and the center CT1 of the first anode electrode AE1 is adjusted according to a chief ray angle CRA, ensuring that the recycling efficiency of light, caused by a filter with thicknesses of less than or equal to about 0.2 μm, can be maintained.

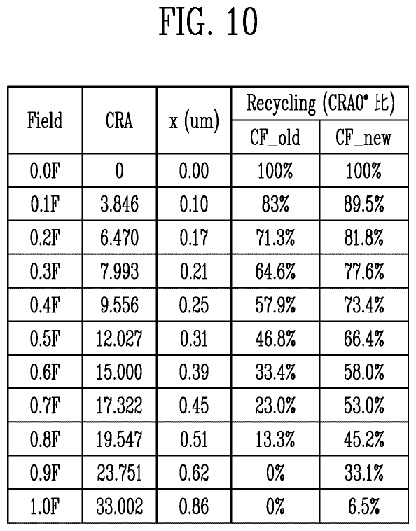

FIG. 10 is a table illustrating an embodiment of a chief ray angle and a shifted distance for each position of the display panel. Referring to FIGS. 8, 9, and 10, a shifted distance x between a center of each filter and a center of a corresponding light emitting element as a function of a chief ray angle CRS for each position (field) of the display area is illustrated in FIG. 10. In FIG. 10, recycling efficiency of the display device DD (see FIG. 6), which uses filters CF_new each including metal layers and a dielectric layer disposed between the metal layers, in which a center of each filter is shifted, is compared to an existing display device using older color filters CF_old.

As shown in FIG. 10, the chief ray angle CRA may increase as the position of a pixel becomes closer to the edge (1.0 F) of the display area from the center (0.0 F) of the display area. For example, in the case where the pixel is located at 0.1 F adjacent to the center (0.0 F) of the display area, the chief ray angle CRA may be about 3.846 degrees. On the other hand, in the case where the pixel is located at 0.9 F further from the center (0.0 F) of the display area, the chief ray angle CRA may increase to about 23.751 degrees. However, since the chief ray angle CRA for each position varies depending on an optical design value, the disclosure is not limited thereto.

As the chief ray angle CRA increases, centers of filters may shift further from centers of anode electrodes. For example, in the case where the chief ray angle CRA is about 3.846 degrees, the centers of the filters may be shifted by about 0.10 μm from the centers of the anode electrodes. In the case where the chief ray angle CRA is about 23.751 degrees, the centers of the filters may be shifted by about 0.62 μm from the centers of the anode electrodes.

In the case where the chief ray angle CRA is greater than about 0 degree and is less than or equal to about 30 degrees, an increase in recycling efficiency may be meaningful. For example, in the case where the centers of the filters are shifted by about 0.10 μm from the centers of the anode electrodes at the chief ray angle CRA of about 3.846 degrees, the recycling efficiency may increase by up to about 89.5%. In the case where the centers of the filters are shifted by about 0.62 μm from the centers of the anode electrodes at the chief ray angle CRA of about 23.751 degrees, the recycling efficiency may increase by up to about 33.1%. As such, in embodiments, in the case where the chief ray angle CRA is greater than about 0 degree and is less than or equal to about 30 degrees, the recycling efficiency can increase by about 193% compared to the existing display device. However, the corresponding numerical values are provided as an example, and the disclosure is not limited thereto.

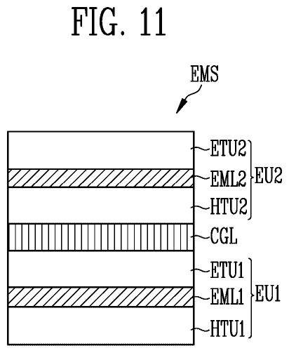

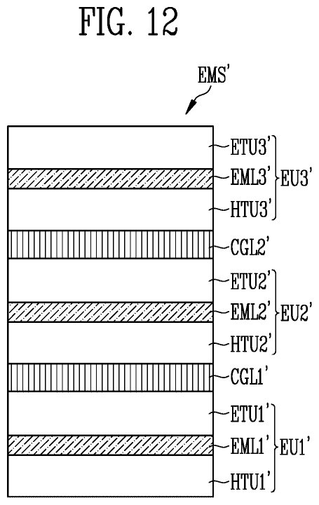

FIGS. 11 and 12 are schematic sectional views illustrating embodiments of a light emitting structure included in any of the first to third light emitting elements shown in FIG. 6.

Referring to FIG. 11, the light emitting structure EMS may have a tandem structure in which first and second light emitting units EU1 and EU2 are stacked. The light emitting structure EMS may be substantially identical in each of the first to third light emitting elements LD1 to LD3 shown in FIG. 6.

Each of the first and second light emitting units EU1 and EU2 may include at least one light emitting layer that generates light in response to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. Similarly, the second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if necessary. The first and second hole transport units HTU1 and HTU2 may have substantially identical configurations or different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if necessary. The first and second electron transport units ETU1 and ETU2 may have substantially identical configurations or different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9, while the n-dopant layer may include an alkali metal, an alkaline earth metal, a lanthanide-based metal, or any combination thereof. However, embodiments are not limited thereto.

In embodiments, the first light emitting layer EML1 and the second light emitting layer EML2 may generate lights of different colors. Lights emitted from the first light emitting layer EML1 and the second light emitting layer EML2 may mix together to produce white light. For example, the first light emitting layer EML1 may emit light of a blue color, and the second light emitting layer EML2 may emit light of a yellow color. In embodiments, the second light emitting layer EML2 may include a first sub-light emitting layer that emits light of a red color and a second sub-light emitting layer that emits light of a green color, which mix together to provide the light of the yellow color. An intermediate layer that performs a function of transporting holes and/or a function of blocking transportation of electrons may be further disposed between the first and second sub-light emitting layers.

In other embodiments, the first light emitting layer EML1 and the second light emitting layer EML2 may emit light of the same color.

The light emitting structure EMS may be formed using a process such as vacuum deposition or inkjet printing, but embodiments are not limited thereto.

Referring to FIG. 12, a light emitting structure EMS' may have a tandem structure in which first to third light emitting units EU1′, EU2′, and EU3′ are stacked. The light emitting structure EMS' may be substantially identical in each of the first to third light emitting elements LD1 to LD3 shown in FIG. 6.

Each of the first to third light emitting units EU1′ to EU3′ may include a light emitting layer that generates light in response to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. Similarly, the second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and an electron blocking layer, and the like, if necessary. The first to third hole transport units HTU1′ to HTU3′ may have substantially identical configurations or different configurations.

Each of the first to third electron transport units ETU1′ to ETU3′ may include at least one of an electron injection layer and an electron transport layer, and further include an electron buffer layer, a hole blocking layer, and the like, if necessary. The first to third electron transport units ETU1′ to ETU3′ may have substantially identical configurations or different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In embodiments, the first to third light emitting layers EML1′ to EML3′ may emit lights of different colors. Lights emitted from the first to third light emitting layers EML1′ to EML3′ may mix together to produce white light. For example, the first light emitting layer EML1′ may emit light of a blue color, the second light emitting layer EML2′ may emit light of a green color, and the third light emitting layer EML3′ may emit light of a red color.

In other embodiments, at least two light emitting layers among the first to third light emitting layers EML1′ to EML3′ may emit light of the same color.

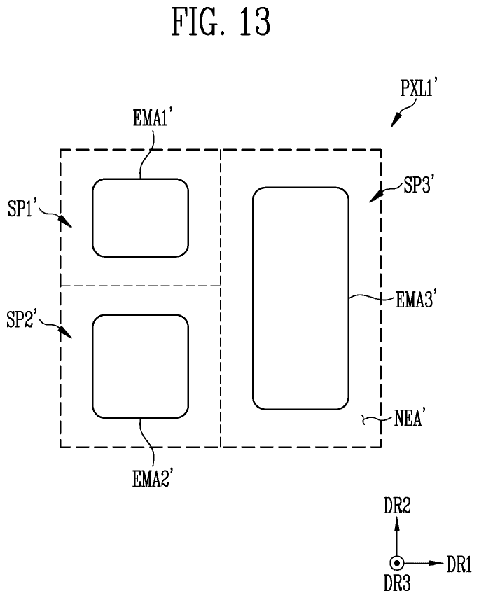

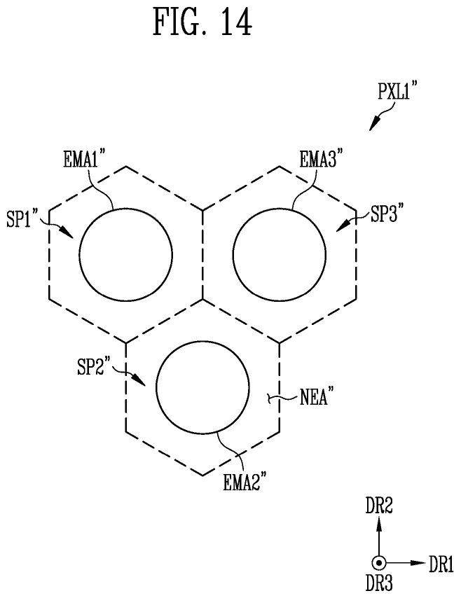

FIGS. 13 and 14 are schematic plan views illustrating other embodiments of the one of the pixels shown in FIG. 4.

Referring to FIG. 13, a first pixel PXL1′ may include first to third sub-pixels SP1′ to SP3′.

The first sub-pixel SP1′ may include a first emission area EMA1′ and a non-emission area NEA′ surrounding the first emission area EMA1′. The second sub-pixel SP2′ may include a second emission area EMA2′ and the non-emission area NEA′ surrounding the second emission area EMA2′. The third sub-pixel SP3′ may include a third emission area EMA3′ and the non-emission area NEA′ surrounding the third emission area EMA3′.

The first sub-pixel SP1′ and the second sub-pixel SP2′ may be arranged along the second direction DR2. The third sub-pixel SP3′ may be disposed in the first direction DR1 relative to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may have substantially the same area, while the third sub-pixel SP3′ may have an area greater than the area of each of the first and second sub-pixels SP1′ and SP2′. As such, the areas of the first to third sub-pixels SP1′ to SP3′ may vary in some embodiments.

Referring to FIG. 14, a first sub-pixel SP1″ may include a first emission area EMA1″ and a non-emission area NEA″ surrounding the first emission area EMA1″. A second sub-pixel SP2″ may include a second emission area EMA2″ and the non-emission area NEA″ surrounding the second emission area EMA2″. A third sub-pixel SP3″ may include a third emission area EMA3″ and the non-emission area NEA″ surrounding the third emission area EMA3″.

The first to third sub-pixels SP1″ to SP3″ may have polygonal shapes when viewed in the third direction DR3. For example, the shapes of the first to third sub-pixels SP1″ to SP3″ may have hexagonal shapes as shown in FIG. 14.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged along the first direction DR1. The second sub-pixel SP2″ may be disposed in a direction (or diagonal direction), inclined at an acute angle relative to the second direction DR2, with respect to the first sub-pixel SP1″.

The arrangements of the sub-pixels shown in FIGS. 5, 13, and 14 are illustrative, and embodiments are not limited thereto. Each pixel may include two or more sub-pixels, and the sub-pixels may be arranged in various manners. Each of the sub-pixels may have various shapes, and an emission area EMA of the sub-pixel may also have various shapes.

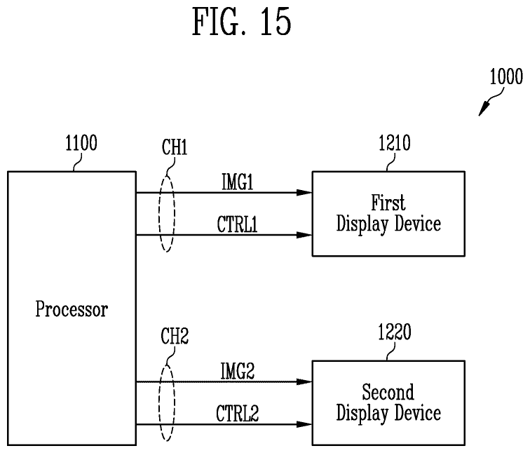

FIG. 15 is a schematic block diagram illustrating an embodiment of a display system.

Referring to FIG. 15, a display system 1000 may include a processor 1100 and one or more display devices 1210 and 1220.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 15, the display system 1000 includes first and second display devices 1210 and 1220. The processor 1100 may be connected to the first display device 1210 through a first channel CH1 and be connected to the second display device 1220 through a second channel CH2.

Through the first channel CH1, the processor 1210 may transmit first image data IMG1 and a first control signal CTRL1 to the first display device 1210. The first display device 1210 may display an image based on the first image data IMG1 and the first control signal CTRL1. The first display device 1210 may be substantially identical to the display device DD described with reference to FIG. 1. The first image data IMG1 and the first control signal CTRL1 may correspond to the input image data IMG and the control signal CTRL shown in FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be substantially identical to the display device DD described with reference to FIG. 1. The second image data IMG2 and the second control signal CTRL2 may correspond to the image data IMG and the control signal CTRL shown in FIG. 1.

The display system 1000 may include a computing system that provides an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

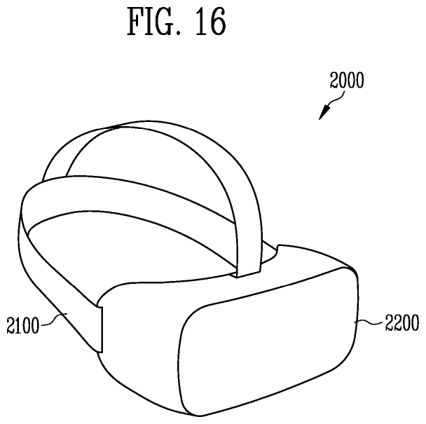

FIG. 16 is a schematic perspective view illustrating an application example of the display system shown in FIG. 15.

Referring to FIG. 16, the display system 1000 from FIG. 15 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band to secure the head mounted display device 2000 to the head of the user. The horizontal band may surround a side portion of the head of the user, while the vertical band may surround an upper portion of the head of the user. However, embodiments are not limited thereto. For example, the head mounting band 2100 may be implemented as a glasses frame, a helmet or the like.

The display device accommodating case 2200 may house the first and second display devices 1210 and 1220 shown in FIG. 15. The display device accommodating case 2200 may further contain the processor 1100 shown in FIG. 15.

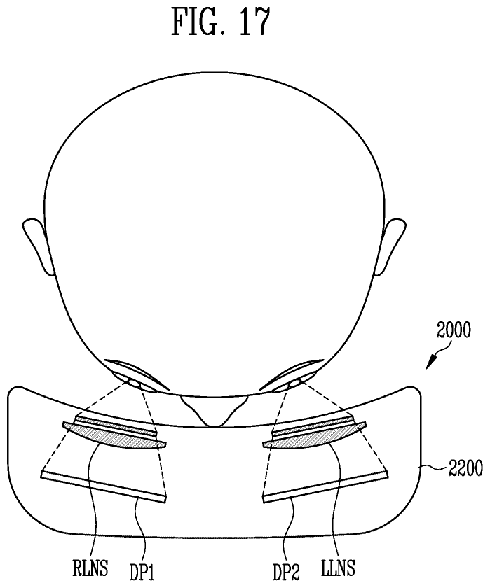

FIG. 17 is a schematic view illustrating a head-mounted display device shown in FIG. 16, as worn by a user.

Referring to FIG. 17, a first display panel DP1 of the first display device 1210 and a second display panel DP2 of the second display device 1220 may be disposed in the head mounted display device 2000. The head mounted display device 2000 may further include one or more lenses, such as a left-eye lens LLNS and a right-eye lens RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user. Each of the right-eye lens RLNS and the left-eye lens LLNS may be a pancake lens, utilizing an optical folding method that refracts a path of light multiple times.

An image output from the first display panel DP1 may be viewed by the right eye of the user through the right-eye lens RLNS. The right-eye lens RLNS may refract light emitted from the first display panel DP1 toward the right eye of the user. The right-eye lens RLNS may perform an optical function to adjust a viewing distance between the first display panel DP1 and the right eye of the user.

Similarly, an image output from the second display panel DP2 may be viewed by the left eye of the user through the left-eye lens LLNS. The left-eye lens LLNS may refract light emitted from the second display panel DP2 toward the left eye of the user. The left-eye lens LLNS may perform an optical function to adjust a viewing distance between the second display panel DP2 and the left eye of the user.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. Each display panel may output images corresponding respectively to the sub-areas of the multi-channel lens, and the user may view the output images through the respective sub-areas.

In the display device in accordance with the embodiments of the disclosure, the filters overlapping the light emitting elements have thicknesses of less than or equal to about 0.2 μm, including first and second metal layers and a dielectric layer, which decreases a distance between an anode electrode and a planarization layer. As the distance between the anode electrode and the planarization layer is decreased, light is recycled through total reflection, thereby improving light extraction efficiency. The distance between the center of each filter and the center of the anode electrode is shifted in an area further from the center of a display area, which has a larger chief ray angle CRA, thereby maintaining the recycling efficiency of light.

The disclosure provides a display device having improved efficiency and a method of manufacturing the display device.

Embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a substrate including a display area and a non-display area surrounding the display area;
a pixel circuit layer disposed on the substrate;
a light emitting element layer disposed on the pixel circuit layer, the light emitting element layer including light emitting elements; and
a filter layer disposed on the light emitting element layer, the filter layer including filters, each filter overlapping a corresponding light emitting element, wherein
each filter includes metal layers and a dielectric layer disposed between the metal layers, and
centers of the filters are shifted from centers of corresponding light emitting elements.

2. The display device of claim 1, wherein
the light emitting elements include anode electrodes disposed on the pixel circuit layer, and
the centers of the light emitting elements align with centers of the anode electrodes.

3. The display device of claim 2, wherein
a center of a first filter among the filters is shifted by a first distance in a first direction or in a second direction intersecting the first direction from a center of a first anode electrode among the anode electrodes, and
a center of a second filter among the filters is shifted by a second distance, different from the first distance, in the first direction or in the second direction from a center of a second anode electrode among the anode electrodes.

4. The display device of claim 3, wherein a first light emitting element including the first anode electrode and a second light emitting element including the second anode electrode among the light emitting elements emit light of a same color.

5. The display device of claim 2, wherein the centers of the filters are shifted by a first distance from the centers of the anode electrodes at a first position adjacent to a center of the display area, and are shifted by a second distance, greater than the first distance, at a second position adjacent to the non-display area.

6. The display device of claim 1, wherein
light emitted from the display device has a chief ray angle for each position of the display area, and
a center of each filter is shifted from a center of a corresponding light emitting element based on the chief ray angle at a corresponding position.

7. The display device of claim 6, wherein the chief ray angle is greater than about 0 degree and less than about 30 degrees.

8. The display device of claim 6, wherein the chief ray angle has a first angle at the first position adjacent to the center of the display area, and a second angle, greater than the first angle, at the second position adjacent to the non-display area.

9. The display device of claim 1, wherein
the light emitting elements include a first light emitting element that emits light of a first color, a second light emitting element that emits light of a second color, and a third light emitting element that emits light of a third color,
the filters include a first filter overlapping the first light emitting element, a second filter overlapping the second light emitting element, and a third filter overlapping the third light emitting element, and
the first, second, and third filters have different thicknesses.

10. The display device of claim 9, wherein
the first color is red,
the second color is green, and
the third color is blue,
a thickness of the first filter is less than a thickness of the second filter, and
a thickness of the third filter is greater than the thickness of the second filter.

11. The display device of claim 9, wherein the dielectric layers of the first, second, and third filters have different thicknesses.

12. The display device of claim 1, wherein the filters have thicknesses of less than or equal to about 0.2 μm.

13. The display device of claim 1, further comprising:
a polarizing layer disposed on the filter layer; and
a phase retardation layer disposed between the filter layer and the polarizing layer.

14. The display device of claim 13, wherein the polarizing layer includes a linear polarizer that transmits linearly polarized light from the display device.

15. The display device of claim 1, wherein
the light emitting elements further include anode electrodes disposed on the pixel circuit layer, and a light emitting structure disposed on the anode electrodes that includes a plurality of light generation layers,
the light emitting structure includes at least two light emitting units that are sequentially stacked, with at least one charge generation layer disposed between the light emitting units, and
each of the at least two light emitting units includes a light emitting layer.

16. A display system, comprising:
a processor to provide input image data; and
a display device to display an image based on the input image data,
wherein the display device comprises: a substrate including a display area and a non-display area surrounding the display area;
a pixel circuit layer disposed on the substrate;
a light emitting element layer disposed on the pixel circuit layer, the light emitting element layer including light emitting elements; and
a filter layer disposed on the light emitting element layer, the filter layer including filters, each filter overlapping a corresponding light emitting element, wherein
each filter includes metal layers and a dielectric layer disposed between the metal layers, and
centers of the filters are shifted from centers of corresponding light emitting elements.
